(19) United States
(12) Patent Application Publication
(10) Pub. No.: US 2017/0207362 A1
(43) Pub. Date: Jul. 20, 2017

(54) METHOD FOR FORMING THIN FILM HAVING SULFIDE SINGLE-CRYSTAL NANOPARTICLES

(71) Applicant: Industrial Technology Research Institute, Hsinchu (TW)

(72) Inventors: Tung-Po Hsieh, Taipei City (TW); Wei-Sheng Lin, Taoyuan County (TW); Jen-Chuan Chang, Taipei City (TW); Yung-Tsung Liu, Taipei City (TW)

(73) Assignee: Industrial Technology Research Institute, Hsinchu (TW)

(21) Appl. No.: 15/479,289

(22) Filed: Apr. 5, 2017

Related U.S. Application Data
(62) Division of application No. 14/583,192, filed on Dec. 26, 2014.

(30) Foreign Application Priority Data
Dec. 22, 2014 (TW) 103144688

(51) Int. Cl. H01L 31/18; H01L 31/0224; H01L 31/0296; H01L 31/032

(52) U.S. Cl. CPC H01L 31/1828; H01L 31/0322; H01L 31/022425; H01L 31/0296; H01L 31/1864

(57) ABSTRACT

A method for forming a thin film having sulfide single-crystal nanoparticles includes dropping a sulfide precursor solution on the surface of a Group VI absorption layer, and then performing thermal decomposition on the sulfide precursor solution under a predetermined temperature to form a thin film consisting of sulfide single-crystal nanoparticles on the surface of the Group VI absorption layer.

### CROSS-REFERENCE TO RELATED APPLICATION

This application is a divisional application of and claims the priority benefit of U.S. application Ser. No. 14/583,192, filed on Dec. 26, 2014, now pending, which claims the priority benefit of Taiwan application serial no. 103144688, filed on Dec. 22, 2014. The entirety of each of the above-mentioned patent applications is hereby incorporated by reference herein and made a part of this specification.

### TECHNICAL FIELD

The disclosure relates to a method for forming a thin film having sulfide single-crystal nanoparticles.

### BACKGROUND

In recent years, due to the rapid development of emerging countries, various energy shortages have occurred, and changes in global climate, environmental pollution, and ecological catastrophe have also become dire. Therefore, pollution-free, scarcity-free solar energy capable of providing adequate long-term worldwide use is the subject of much attention and expectation of various industries. In its current state, electricity generated by solar energy still cannot replace the current fossil energy, and the main reason is higher cost and instability in the time of power supply. However, in the long term, the necessary reduction in the amount of carbon dioxide causing greenhouse effect and the day of total depletion of fossil fuel have made countries around the world gather efforts to subsidize the development of the solar energy industry in the hopes of making solar energy the mainstream energy in the future via the development of manufacturing techniques of solar energy.

Currently, cost reduction is one of the important topics of the solar cell, and therefore Group VI compound solar cells having low costs have become popular in recent years.

The literal interpretation of the Group VI solar cell is a material containing a Group VIA element from the Periodic Table, containing: an element such as oxygen (O), sulfur (S), selenium (Se), or tellurium (Te). The Group II material is mainly the Group IIB materials zinc (Zn) and cadmium (Cd), wherein the compound cadmium telluride (CdTe) can be considered as the most representative Group II-VI solar cell material, the structure is zinc blende. The Group I-III-VI material is a variation of Group II-VI and is derived from a Group II-VI compound, wherein a Group IB element (Cu or Ag) and a Group IIIA element (In, Ga, or Al) are used to replace the Group IIB element so as to four the so-called chalcopyrite structure, and representative battery materials such as the compounds of copper indium selenide (CuInSe₂), copper indium gallium selenide (CuInGaSe₂), and copper zinc tin sulfur selenide (Cu₂ZnSn(S,Se)₄) have been developed for several decades. As a result, the research of Group VI solar cell materials is relatively mature.

The absorption layer of such thin film solar cell typically includes an n-type CdS or ZnS layer as the joint interface of the semiconductor, and the manufacturing process thereof includes, for instance, close-spaced sublimation (CSS), vapor deposition, or chemical bath deposition (CBD). However, the temperature of the most commonly used CBD is generally controlled at 65° C. to 75° C., and thus if the temperature in a subsequent process is too high, then severe deterioration to devices occurs, causing damage to the joint interface. As a result, subsequent processes (such as forming of the transparent electrode) all cannot be performed at higher temperature. Moreover, the CBD further has the issue of waste liquid, which causes the wastewater treatment to be extremely expensive and complex, and may also increase concern for environmental pollution and ecological impact.

In addition to the CBD process, many process techniques can manufacture an n-type CdS or ZnS layer, such as the vacuum process. However, the costs of vacuum equipment are high, production yield is low, and technical bottleneck is high, such that the vacuum process cannot be readily adapted for commercial production, thus limiting market development.

### SUMMARY

The disclosure provides a method for forming a thin film having sulfide single-crystal nanoparticles. The method is capable of forming a thin film composed of single-crystal nanoparticles and having high coverage, the thickness can be precisely controlled in nanoscale, and effects such as no material loss, low chemical waste liquid, and simple process can be achieved.

A method for forming a thin film having sulfide single-crystal nanoparticles of the disclosure includes dropping a sulfide precursor solution on the surface of a Group VI absorption layer, and then performing thermal decomposition on the sulfide precursor solution under a predetermined temperature to form a thin film consisting of sulfide single-crystal nanoparticles on the surface of the Group VI absorption layer.

In order to make the aforementioned features of the disclosure more comprehensible, embodiments accompanied with figures are described in detail below.

### BRIEF DESCRIPTION OF THE DRAWINGS

FIG. 1 is a three-dimensional schematic of a compound solar cell according to an embodiment of the disclosure.

FIG. 2A to FIG. 2C are the flow charts of a manufacturing process of a thin film having sulfide single-crystal nanoparticles according to another embodiment of the disclosure.

FIG. 3 is a graph of the three-stage co-evaporation of the CIGS thin film of preparation example 1.

FIG. 4 is an SEM image of ZnS of preparation example 2.

FIG. 5 is an SEM image of ZnS of example 1.

FIG. 6 is a TEM image of ZnS of example 1.

FIG. 7 is an SEM image of the cross-section of the solar cell of the comparative example.

FIG. 8 is a graph of photoelectric conversion efficiency of the solar cells of the comparative example.

FIG. 9 is a schematic of the CIGS solar cell of example 2-1.

FIG. 10 is an SEM image of the cross-section of the solar cell of example 2-1.

FIG. 11 is a graph of photoelectric conversion efficiency of the solar cells of the comparative example and example 2-1.

FIG. 12 is an I-V graph of the solar cell of example 2-1.

FIG. 13 is an I-V graph of the solar cell of example 2-3.

### DETAILED DESCRIPTION OF DISCLOSED EMBODIMENTS

In the following, each embodiment of the disclosure is more comprehensively described with reference to figures. Each embodiment of the disclosure can also be expressed in many different forms, and should not be construed as limited to the embodiments listed in the present specification. Specifically, the embodiments are provided to make the disclosed contents more thorough and more complete, and to fully convey the concept of each embodiment to those having ordinary skill in the art. In the figures, the thickness of each layer or each region is enlarged for clarity.

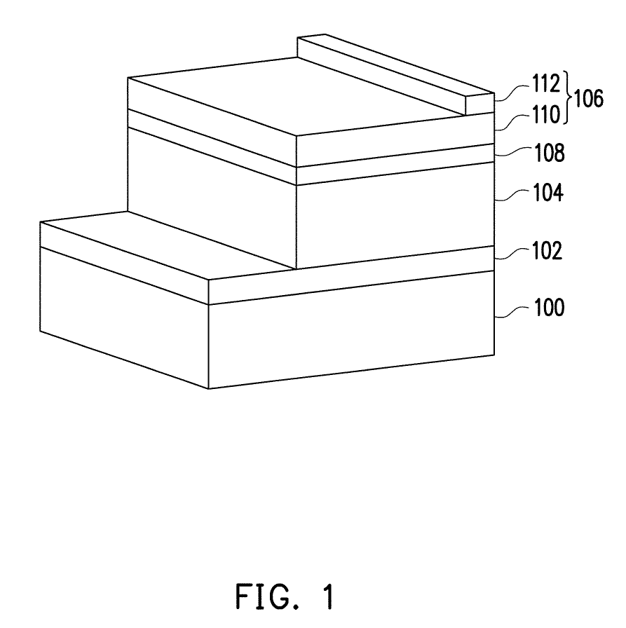

FIG. 1 is a three-dimensional schematic of a compound solar cell according to an embodiment of the disclosure.

Referring to FIG. 1, a compound solar cell of the present embodiment includes a substrate 100, a first electrode 102, a Group VI absorption layer 104, and a second electrode 106. The Group VI absorption layer 104 can be a Group compound or a Group II-VI compound such as copper indium gallium selenium (CIGS), copper zinc tin sulfur (CZTS), or cadmium telluride (CdTe). The first electrode 102 is, for instance, a metal electrode, and the second electrode 106 can include a transparent electrode 110 and a metal grate line 112. Moreover, a first buffer layer 108 is between the second electrode 106 and the Group VI absorption layer 104, and the first buffer layer 108 is a thin film consisting of sulfide single-crystal nanoparticles. Since the first buffer layer 108 is a thin film composed of single-crystal structures, the first buffer layer 108 is resistant to high temperature. Therefore, when the second electrode 106 is subsequently formed, processes such as sputtering and deposition can be performed at a higher temperature, so as to obtain a transparent electrode having better conductivity and transparency. The thickness of the first buffer layer 108 is, for example, one embodiment between about 1 nm and about 150 nm; another embodiment between 2 nm and 30 nm. When the thickness of the first buffer layer 108 is 1 nm or greater, the first buffer layer 108 can play the role of protecting the surface of the Group VI absorption layer 104 in a subsequent battery process, so as to prevent damage from plasma; when the thickness of the first buffer layer 108 is 150 nm or less, reduction in battery efficiency due to excessive series resistance can be prevented. When the first buffer layer 108 is smaller than 1 nm, leakage current of the battery caused by incomplete coverage readily occurs, and when the first buffer layer 108 is greater than 150 nm, the series resistance of the battery is increased and transmittance of light is reduced. The material forming the sulfide single-crystal nanoparticles of the first buffer layer 108 is, for instance, ZnS, CdS, InS, PbS, FeS, CoS₂, Cu₂S, MoS₂ and so on. The particle size of the sulfide single-crystal nanoparticles is, for instance, between 1 nm and 20 nm. In an embodiment, a second buffer layer (not shown) can be further included. The second buffer layer is, for instance, an i-ZnO layer, is disposed between the first buffer layer 108 and the transparent electrode 110, and the thickness of the second buffer layer is, for instance, between about 0.1 nm and about 100 nm.

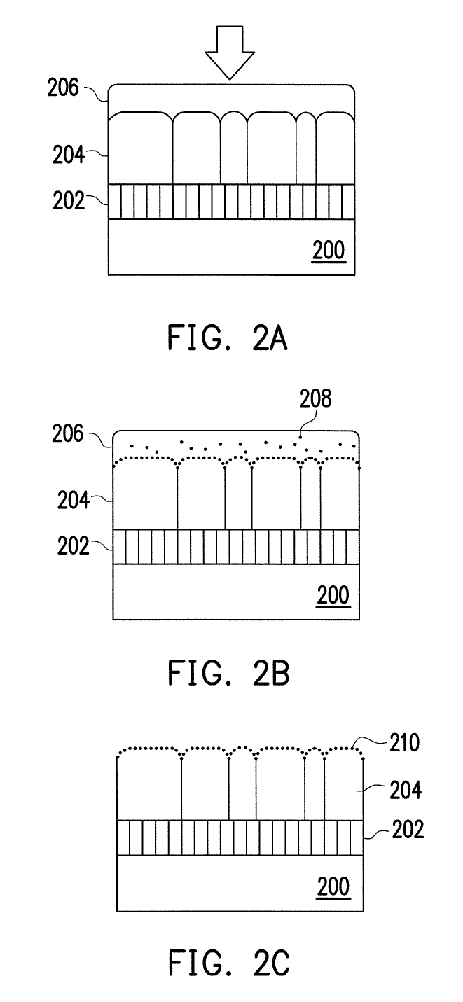

FIG. 2A to FIG. 2C are the flow charts of a manufacturing process of a thin film having sulfide single-crystal nanoparticles according to another embodiment of the disclosure.

The present embodiment is exemplified by a compound solar cell; in other words, the thin film having sulfide single-crystal nanoparticles to be formed is used as the first buffer layer. Therefore, referring to FIG. 2A, a structure including a substrate 200, a first electrode 202, and a Group VI absorption layer 204 is first prepared, and then a sulfide precursor solution 206 is dropped on the surface of a Group VI absorption layer 204. The sulfide precursor solution 206 includes a solvent and a sulfide precursor, wherein the sulfide precursor is, for instance, zinc diethyldithiocarbamate (chemical formula: [(C₂H₅)₂NCS₂]₂Zn), cadmium diethyldithiocarbamate, indium diethyldithiocarbamate, lead diethyldithiocarbamate, iron diethyldithiocarbamate, cobalt diethyldithiocarbamate, copper diethyldithiocarbamate, etc. The boiling point of the solvent in the sulfide precursor solution 206 is, for instance, 220° C. or greater; for instance, between 220° C. and 350° C., and is resistant to high-temperature treatment. The solvent is, for instance, trioctylphosphine (TOP) or other suitable solvents. The concentration of the sulfide precursor solution 206 is, for instance, between 0.01 M and 0.6 M, and when the concentration is 0.01 M or greater, the speed of forming the sulfide single-crystal nanoparticles is not too slow; when the concentration is 0.6 M or less, unevenness due to excessive particle size does not occur to the formed thin film.

Then, referring to FIG. 2B, a thermal decomposition is performed on the sulfide precursor solution 206 under a first predetermined temperature, and sulfide single-crystal nanoparticles 208 are gradually formed in the meantime. The thermal decomposition is preferably performed in an inert gas (such as nitrogen or argon) or in vacuum, and the first predetermined temperature is, for instance, between 220° C. and 350° C.

Afterwards, referring to FIG. 2C, a thin film 210 consisting of the sulfide single-crystal nanoparticles are formed on the surface of the Group VI absorption layer 204.

In addition to the above steps, before the step in FIG. 2A, preheating can first be performed to a second predetermined temperature such as 100° C. to 200° C., and after dropping the sulfide precursor solution 206 on the surface of the Group VI absorption layer 204, the heating can be performed to the first predetermined temperature. After forming the thin film 210, the remaining sulfide precursor is optionally washed off with acetone or alcohol and drying is then performed with an inert gas (such as nitrogen) after the temperature is down to room temperature. Afterwards, if needed, baking can be performed under a high temperature such as 150° C. to 300° C. to completely remove the solvent in the sulfide precursor solution 206.

Several experiments are listed below to verify the efficacy of the disclosure. However, the scope of the disclosure is not limited to the following experiments.

### Preparation Example 1

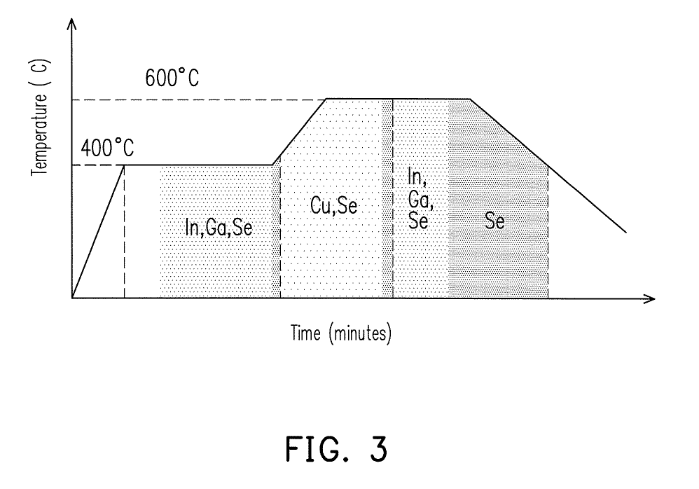

A molybdenum metal layer (thickness: about 800 nm to about 1 μm) was sputtered on a solid lime glass (SLG) substrate as a first electrode, and then a CIGS thin film having a thickness of about 2 μm to about 2.5 μm was deposited on the molybdenum metal as a Group VI absorption layer. In the present preparation example, the CIGS thin film was formed via an NREL three-stage co-evaporation method. In the first stage, a In₂Se₃ compound and a Ga₂Se₃ compound were first evaporated, and then in the second stage, in the presence of only Cu and Se, a Cu-rich CIGS thin film was formed. At this point, a CuₓSe₁₋ₓ compound was formed, which facilitates the growth of thin film crystal particles. Lastly, in the third stage, In, Ga, and Se were evaporated such that the thin film thereof was reverted back to In-rich. The graph of the three-stage co-evaporation is as shown in FIG. 3.

### Preparation Example 2

A ZnS first buffer layer (thickness: about 50 nm) was formed on the CIGS thin film of preparation example 1 via chemical bath deposition (CBD).

The steps of the CBD of the present preparation example are as follows:
1. 2 M of thiourea solution and 0.16 M of zinc sulfate solution were prepared.
2. The thiourea solution was first poured into a pot, and then heated to 70-80° C.
3. Cu₂₋ₓSe on the surface of CIGS can be removed via 5% of KCN solution as needed, and then KCN was washed off via deionized water.
4. 150 ml of 7 M ammonia solution and zinc sulfate solution were mixed in the glass pot.
5. The entire glass substrate was immersed for about 20 minutes, and the reaction temperature was kept at 80-85° C.
6. After the deposition was complete, the glass substrate was removed and the reaction solution on the CIGS surface was washed off with deionized water, and then the glass substrate was dried via compressed air to complete the first buffer layer deposition.

### Example 1

Via the method of the disclosure, a first buffer layer consisting of ZnS single-crystal nanoparticles was formed on the CIGS thin film of preparation example 1.

The manufacture of the first buffer layer of the example was performed under a nitrogen environment, and preheating was first performed at 100° C. and a time of 3 minutes via a hot plate to evenly heat the glass substrate. Then, 0.28 ml of a nanocrystal precursor (solvent: TOP) of 0.1 M of zinc diethyldithiocarbamate ([(C₂H₅)₂NCS₂]₂Zn) was dropped on the CIGS layer, and a thermal decomposition was performed, and at this point, the heating temperature was increased to 290° C., and the heating time was about 5-7 minutes.

Then, the temperature was reduced to room temperature at about 25° C. for about 10 minutes. After the thermal decomposition was complete, the test piece was removed, and after washing with acetone and alcohol, the surface of the test piece was dried with nitrogen to remove remaining organic matter.

Lastly, the test piece was heated to 150-200° C. for about 10 minutes under atmospheric environment via a hot plate, or the test piece was placed under a solar simulator having a light intensity of 1 SUN and irradiated for about 1 hour to about 2 hours to complete the manufacture of the first buffer layer. In the present embodiment, the thickness of the first buffer layer is about 50 nm.

### Analysis 1

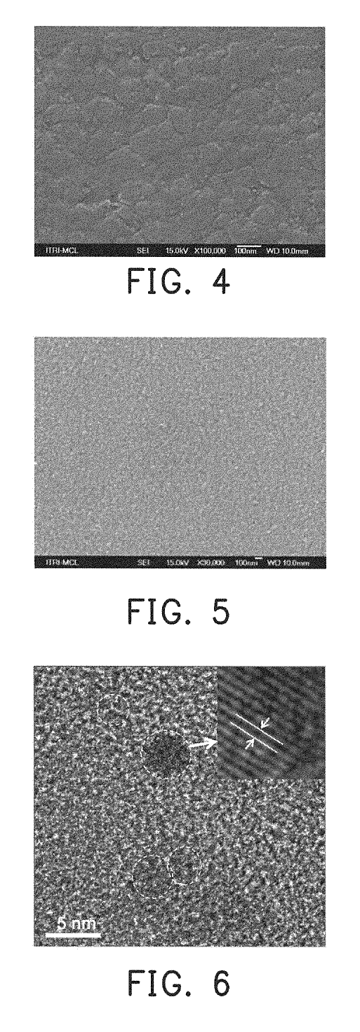

The surface images of ZnS of the preparation example 2 and the example 1 were obtained via SEM, which are respectively shown in FIG. 4 and FIG. 5.

It can be known from the comparison that, in FIG. 4, the ZnS surface prepared by CBD is a thin film made up of stacked crystal particles, but in FIG. 5, the ZnS surface formed by thermal decomposition is made up of nanoparticles in stacked arrangement, which is different from the ZnS thin film grown in FIG. 4.

Then, the ZnS crystals in example 1 were analyzed via TEM (JOEL 2100F), a portion of the solution was taken from the test piece, and after centrifugation and washing, ZnS nanoparticles having a particle size of about 1-3 nm were observed, and were confirmed to be single-crystal particles via high-resolution TEM. For instance, the circled portion of FIG. 6 represents a single-crystal nanoparticle. Although FIG. 6 only shows several circles, it should be known that, in an image taken by high-resolution TEM, darker points are single-crystal particle structures. For instance, the upper right of FIG. 6 shows the crystal lattice of a single-crystal particle thereof.

### Comparative Example

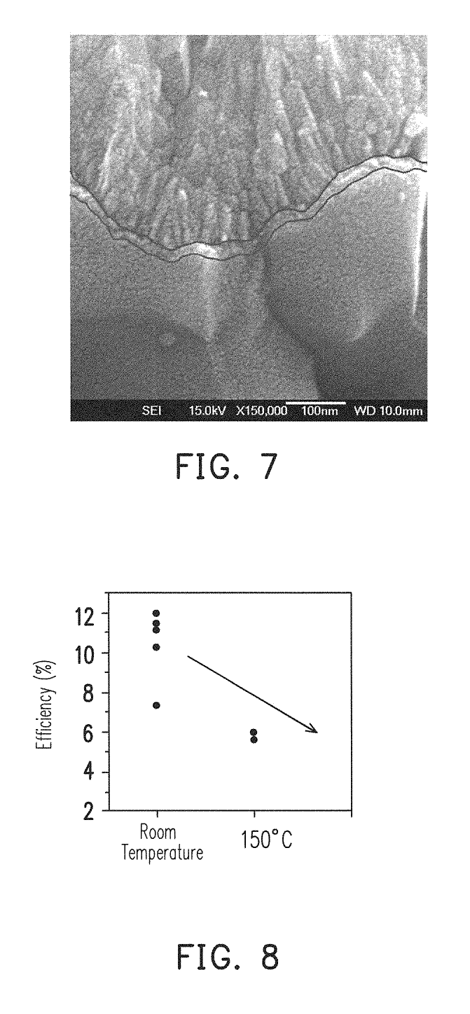

About 50 nm of i-ZnO was grown on the ZnS first buffer layer of preparation example 2 under room temperature via a sputtering method as a second buffer layer. Then, about 500 nm of AZO was grown under room temperature as a transparent electrode. After observing via SEM, FIG. 7 was obtained. Lastly, the manufacture of Ni-Al as an upper electrode was completed via a sputtering method.

Since the coating film of the CBD process is bad for temperature stability, when the temperature of a subsequent process exceeds 150° C., expected element characteristics are deteriorated. Therefore, the photoelectric conversion efficiencies of solar cells of two different AZO process temperatures were measured, and the results are shown in FIG. 8.

It can be known from FIG. 8 that once the AZO process temperature is increased, the photoelectric conversion efficiency of the CIGS solar cells with ZnS buffer layer made by the CBD process is significantly reduced.

### Example 2-1

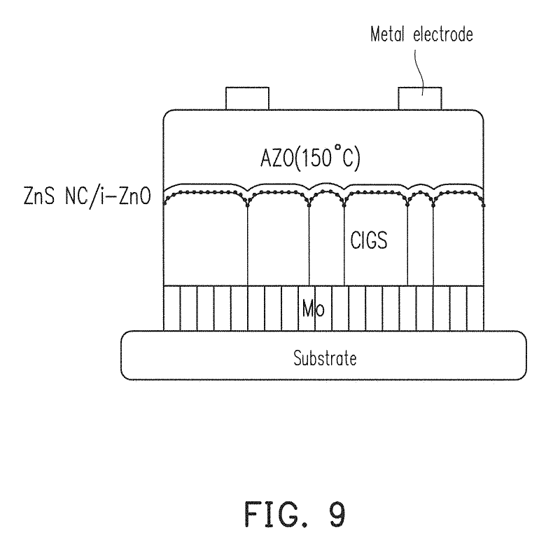

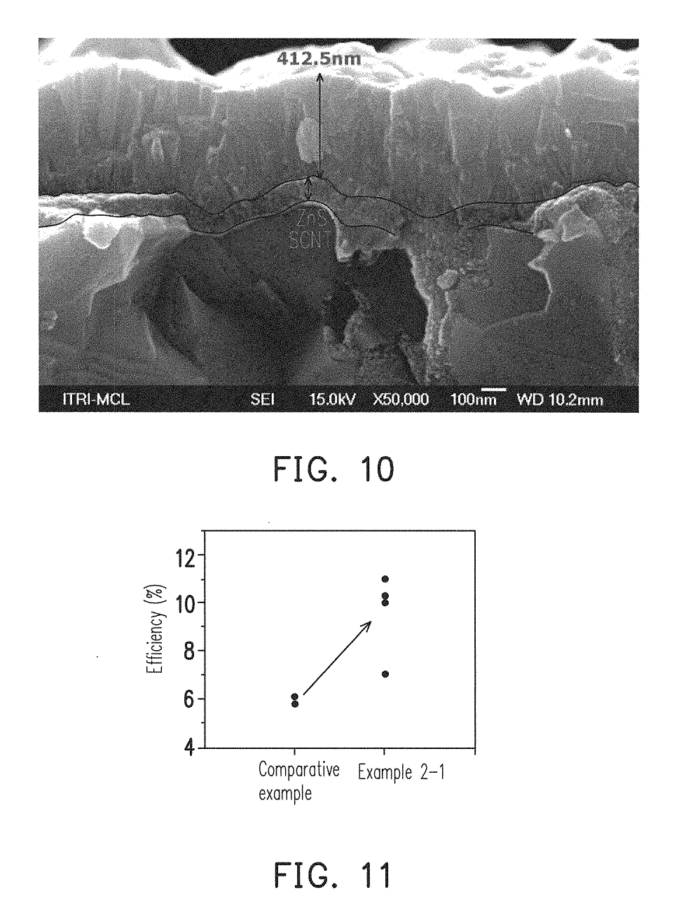

To manufacture the CIGS solar cell shown in FIG. 9, about 50 nm of i-ZnO layer as a second buffer layer was grown on the ZnS first buffer layer of example 1 under room temperature via a sputtering method. Then, about 500 nm of AZO was grown in a high-temperature environment of about 150° C. as a transparent electrode. After observing via SEM, FIG. 10 was obtained, and it can be observed from FIG. 10 that the ZnS first buffer layer (ZnS) is a thin film consisting of particles. Lastly, a Ni/Al metal electrode was formed on the AZO transparent electrode.

The conversion efficiency characteristics of the CIGS solar cell of the present example 2-1 and the CIGS solar cell of the comparative example (AZO process temperature was also 150° C.) were measured, and the results are shown in FIG. 11.

It can be known from FIG. 11 that, for the solar cell with the thin film consisting of the ZnS single-crystal nanoparticles of example 2-1 and the AZO formed by a high-temperature process (150° C.), the conversion efficiency thereof has no significant change and is about 10.9%. In comparison with the comparative example (FIG. 8), once the subsequent AZO process temperature increases to 150° C., the conversion efficiency will be reduced to only 6.3%. Accordingly, in contrast to the buffer layer made by the CBD process, the conversion efficiency is increased from 6.3% to 10.9% as per the structure and method of the example 2-1, indicating the effect of increasing device efficiency.

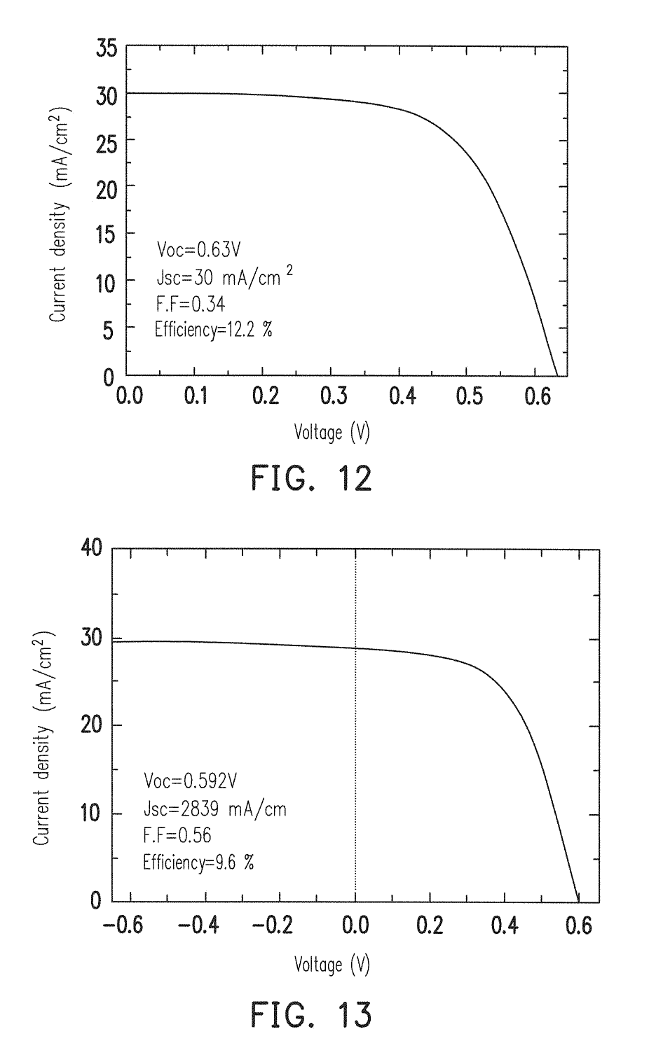

Referring to FIG. 12 at the same time, the thickness of each layer of the CIGS solar cell of example 2-1 can also be adjusted to reach a higher efficiency of about 12.2%.

### Example 2-2

The compound solar cell was manufactured via the same method as example 2-1 except that CIGS was changed to CZTS, wherein the thickness of the CZTS absorption layer is about 2 μm, and the composition ratios are: Cu/(Zn+Sn): about 0.8, Zn/Sn: about 1.05. After measurement, the current device conversion efficiency can reach 2.46% (Voc: 0.35 V, Jsc: 25.51 mA/cm², F.F.: 28%) after light soaking.

### Example 2-3

The compound solar cell was manufactured via the same method as example 2-1 except that the ZnS single-crystal nanoparticles were changed to cadmium sulfide (CdS) single-crystal nanoparticles to form a first buffer layer, and the difference between the manufacture thereof and that of example 2-1 is that cadmium diethyldithiocarbamate ([(C₂H₅)₂NCS₂]₂Cd) was used as the nanocrystal precursor, followed by an AZO process at 150° C. to complete the manufacture of the compound solar cell. The thickness of the CdS first buffer layer is about 88 nm, and the device efficiency thereof is about 9.6%, as shown in FIG. 13.

Based on the above, in the disclosure, since a thin film consisting of sulfide single-crystal nanoparticles is used as the first buffer layer of the compound solar cell, it may not only accomplish low process costs but also save process time and increase productivity, and the generation of waste liquid can also be reduced. Moreover, since the first buffer layer is a single-crystal structure, the temperature of subsequent process can be increased, thus improving overall device characteristics.

Although the disclosure has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A method for forming a thin film having sulfide single-crystal nanoparticles, comprising:
dropping a sulfide precursor solution on a surface of a Group VI absorption layer; and
performing a thermal decomposition on the sulfide precursor solution under a first predetermined temperature to form a thin film consisting of a plurality of sulfide single-crystal nanoparticles on the surface of the Group VI absorption layer.

2. The method of claim 1, wherein the sulfide precursor solution comprises a solvent and a sulfide precursor.

3. The method of claim 2, wherein the sulfide precursor comprises zinc diethyldithiocarbamate, cadmium diethyldithiocarbamate, indium diethyldithiocarbamate, lead diethyldithiocarbamate, iron diethyldithiocarbamate, cobalt diethyldithiocarbamate, or copper diethyldithiocarbamate.

4. The method of claim 2, wherein a boiling point of the solvent is 220° C. or greater.

5. The method of claim 2, wherein the solvent comprises trioctylphosphine (TOP).

6. The method of claim 1, wherein a concentration of the sulfide precursor solution is between 0.01 M and 0.6 M.

7. The method of claim 1, wherein the thermal decomposition is performed in an inert gas or vacuum.

8. The method of claim wherein the first predetermined temperature is between 220° C. and 350° C.

9. The method of claim 1, further comprising, before dropping the sulfide precursor solution on the surface of the material layer, preheating to a second predetermined temperature, wherein the second predetermined temperature is 100° C. to 200° C.; and heating to the first predetermined temperature of between about 220° C. and about 350° C. after the sulfide precursor solution is dropped on the surface of the material layer.
